(19) United States
(12) Patent Application Publication
(10) Pub. No.: US 2025/0309050 A1
(43) Pub. Date: Oct. 2, 2025

(54) INLET AND OUTLET LOCATIONS AND STANDARDIZATION

(71) Applicant: Adeia Semiconductor Bonding Technologies Inc., San Jose, CA (US)

(72) Inventors: Belgacem Haba, Saratoga, CA (US); Rajesh Katkar, Milpitas, CA (US)

(21) Appl. No.: 18/751,033

(22) Filed: Jun. 21, 2024

Related U.S. Application Data
(60) Provisional application No. 63/571,940, filed on Mar. 29, 2024.
(60) Provisional application No. 63/651,842, filed on May 24, 2024.

(51) Int. Cl. H01L 23/473; H01L 23/00; H01L 23/31; H01L 23/498; H01L 25/065

(52) U.S. Cl. CPC H01L 23/473; H01L 23/49811; H01L 24/73; H01L 25/0655; H01L 23/3121; H01L 24/16; H01L 24/32; H01L 2224/16225; H01L 2224/32225; H01L 2224/73204

(57) ABSTRACT

An integrated cooling assembly comprising a semiconductor device; an opening adaptor comprising an inlet opening, an outlet opening, sidewalls, and a divider between the sidewalls; and a cold plate attached between the semiconductor device and the opening adaptor, the cold plate comprising a first opening and a second opening spaced apart by a first distance and in fluid communication with a coolant channel, wherein: at least a portion of a first side of the cold plate is spaced apart from the semiconductor device to define the coolant channel therebetween; the sidewalls and the divider of the opening adaptor extend downwardly to a second side of the cold plate to define an inlet chamber volume and an outlet chamber volume therebetween; the inlet and outlet openings of the opening adaptor are spaced apart by a second distance different from the first distance; and the coolant channel is in fluid communication with the inlet chamber volume and the outlet chamber volume via the first and second openings of the cold plate.

### CROSS-REFERENCE TO RELATED APPLICATIONS

This application claims the benefit of U.S. Provisional Patent Application No. 63/571,940 filed Mar. 29, 2024, and U.S. Provisional Patent Application No. 63/651,842 filed May 24, 2024, each of which is hereby incorporated by reference herein in its entirety.

### FIELD

The present disclosure relates to advanced packaging for microelectronic devices, and in particular, cooling systems for device packages and methods of manufacturing the same.

### BACKGROUND

Energy consumption poses a critical challenge for the future of large-scale computing as the world's computing energy requirements are rising at a rate that most would consider unsustainable. Some models predict that the information, communication and technology (ICT) ecosystem could exceed 20% of global electricity use by 2030, with direct electrical consumption by large-scale computing centers accounting for more than one-third of that energy usage. A significant portion of the energy used by such large-scale computing centers is devoted to cooling since even small increases in operating temperatures can negatively impact the performance of microprocessors, memory devices, and other electronic components. While some of this energy is expended to operate the cooling systems that are directly cooling the chips (e.g. heat spreaders, heat pipes, etc.), energy consumption/costs for indirect cooling can also be quite staggering. Indirect cooling energy costs include, for example, cooling or air conditioning of data center buildings. Data center buildings can house thousands, to tens of thousands or more, of high performance chips in server racks and each of those high performance chips is a heat source. An uncontrolled ambient temperature in a data center will adversely affect the performance of the individual chips and the data center system performance as a whole.

Thermal dissipation in high-power density chips (semiconductor devices/die) is also a critical challenge as improvements in chip performance, e.g., through increased gate or transistor density due to advanced processing nodes, evolution of multi-core microprocessors, etc. have resulted in increased power density and a corresponding increase in thermal flux that contributes to elevated chip temperatures. Higher density of transistors also increases the length of metal wiring on the chips, which generates its own additional thermal flux due to Joule heating of these wires due to higher currents. These elevated temperatures are undesirable as they can degrade the chip's operating performance, efficiency, reliability, and remaining life. Cooling systems used to maintain the chip at a desired operating temperature typically remove heat using one or more heat dissipation devices, e.g., thermal spreaders, heat pipes, cold plates, liquid cooled heat pipe systems, thermal-electric coolers, heat sinks, etc. One or more thermal interface material(s), such as, for example, thermal paste, thermal adhesive, or thermal gap filler, may be used to facilitate heat transfer between the surfaces of a chip and heat dissipation device(s). A thermal interface material(s) (TIM(s)) is any material that is inserted between two components to enhance the thermal coupling therebetween. Unfortunately, the combined thermal resistance of (i) the thermal resistance of interfacial boundary regions between a TIM(s) and the chip and/or the heat dissipation device(s); and (ii) the thermal resistance of a thermal interface material(s) itself can inhibit heat transfer from the chip to the heat dissipation devices, undesirably reducing the cooling efficiency of the cooling system.

Generally speaking, there are multiple components between the heat dissipating sources (i.e., active circuitry) in the chips and the heat dissipation devices, each of which contribute to the system thermal resistance accumulatively along the heat transfer paths and raise chip junction temperatures from the ambient.

Additionally, semiconductor devices often contain regions with varying power densities. These regions may require different cooling methods to achieve optimal performance, cooling efficiency, and compatibility in use. For example, a low power density region may be effectively cooled using air cooling (e.g. heat spreader, heat pipe, etc.), while a high power density region may necessitate liquid cooling.

However, implementing separate cooling methods for distinct regions within a semiconductor device can present challenges. Different cooling techniques often require varying amounts of physical space. Combining air and liquid cooling methods in a hybrid approach can reduce the overall efficiency and compatibility of the device.

Thus, such cooling systems can suffer from reduced cooling efficiency due to the design and manufacture of system components.

Accordingly, there exists a need in the art for improved energy-efficient cooling systems, by reducing system thermal resistance, and methods of manufacturing the same.

### SUMMARY

Embodiments herein provide integrated cooling assemblies for device packages and methods of manufacturing the same.

Advantageously, the integrated cooling assemblies deliver effective cooling to a semiconductor device in a hybrid air-liquid cooling approach that improves the overall efficiency and compatibility of the device.

One general aspect includes an integrated cooling assembly comprising a semiconductor device, an opening adaptor comprising an inlet opening, an outlet opening, sidewalls, and a divider between the sidewalls, a cold plate attached between the semiconductor device and the opening adaptor. The cold plate comprising a first opening and a second opening spaced apart by a first distance and in fluid communication with a coolant channel, wherein a first side of the cold plate is spaced apart from the semiconductor device to define the coolant channel therebetween. The sidewalls and the divider of the opening adaptor extend downwardly to a second side of the cold plate to define an inlet chamber volume and an outlet chamber volume therebetween. The inlet and outlet openings of the opening adaptor are spaced apart by a second distance different from the first distance; and the coolant channel is in fluid communication with the inlet chamber volume and the outlet chamber volume via the first and second openings of the cold plate.

A second general aspect includes an integrated cooling assembly comprising: an opening adaptor comprising an inlet opening, an outlet opening, sidewalls, and a divider between the sidewalls; and a cold plate comprising a first opening and a second opening spaced apart by a first distance and in fluid communication with a coolant channel, wherein the sidewalls and the divider of the opening adaptor extend downwardly to the cold plate to define an inlet chamber volume and an outlet chamber volume therebetween; the inlet and outlet openings of the opening adaptor are spaced apart by a second distance different from the first distance; and the coolant channel is in fluid communication with the inlet chamber volume and the outlet chamber volume via the first and second openings of the cold plate.

A third general aspect includes an integrated cooling assembly comprising: an opening adaptor comprising an inlet opening, an outlet opening, sidewalls, and a divider between the sidewalls; and a cold plate comprising a first opening and a second opening spaced apart by a first distance and in fluid communication with a coolant channel, wherein: the sidewalls and the divider of the opening adaptor extend downwardly to the cold plate to define an inlet chamber volume and an outlet chamber volume therebetween; the inlet and outlet openings of the opening adaptor are spaced apart by a second distance different from the first distance; and the coolant channel is in fluid communication with the inlet chamber volume and the outlet chamber volume via the first and second openings of the cold plate.

A fourth general aspect includes a method of manufacturing an integrated cooling assembly, the method comprising: forming an opening adaptor comprising: etching a first side of the opening adaptor to form a first inlet opening and a first outlet opening spaced apart by a first distance, etching a second side of the opening adaptor to form sidewalls, and a divider between the sidewalls; forming a cold plate comprising an inlet opening and an outlet opening spaced apart by a second distance, and directly bonding the second side of the adaptor to the cold plate.

### BRIEF DESCRIPTION OF THE DRAWINGS

The above and other objects and advantages of the disclosure will be apparent upon consideration of the following detailed description, taken in conjunction with the accompanying drawings, in which:

FIG. 1 illustrates a device package with an external heat sink;

FIG. 2A is a schematic plan view of an example of a system panel, in accordance with embodiments of the disclosure;

FIG. 2B is a schematic partial sectional side view of a device package mounted on a PCB, in accordance with embodiments of the disclosure;

FIG. 2C is a schematic exploded isometric view of the device package in FIG. 2B.

FIG. 3A is a schematic sectional view of an example device package, in accordance with embodiments of the present disclosure, that may be used with the system panel;

FIG. 3B is a schematic sectional view of an integrated cooling assembly of the device package, according to some embodiments;

FIG. 4 is a schematic sectional view of another example device package, in accordance with embodiments of the present disclosure, that may be used with the system panel;

FIG. 5 shows a method that can be used to manufacture the device package described herein.

FIG. 6 illustrates an integrated cooling assembly according to one or more embodiments.

FIG. 7 illustrates a top view of another integrated cooling assembly according to one or more embodiments.

FIG. 8 illustrates a sectional view of another integrated cooling assembly according to one or more embodiments.

FIG. 9 illustrates a sectional view of another integrated cooling assembly according to one or more embodiments.

FIG. 10 illustrates a sectional view of another integrated cooling assembly according to one or more embodiments.

FIG. 11 shows a method of using a device package in accordance with one or more embodiments;

FIG. 12 shows a method that can be used to manufacture an integrated cooling assembly in accordance with one or more embodiments;

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

As used herein, the term “substrate” means and includes any workpiece, wafer, or article that provides a base material or supporting surface from which or upon which components, elements, devices, assemblies, modules, systems, or features of the heat-generating devices, packaging components, and cooling assembly components described herein may be formed or mounted. The term substrate also includes “semiconductor substrates” that provide a supporting material upon which elements of a semiconductor device are fabricated or attached, and any material layers, features, and/or electronic devices formed thereon, therein, or therethrough. Examples of substrate material that may be used in applications that generate high thermal density include, but are not limited to, Si, GaN, SiC, InP, GaP, InGaN, AlGaInP, AlGaAs, etc.

As described below, the semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active sides” and “non-active sides” are also used to describe surfaces of material layers or features formed on, in, or through the semiconductor substrate, whether or not the material layers or features are ultimately present in the fabricated or assembled device. For example, in some instances, the term “active side” is used to indicate a surface of a substrate that will in the future, but does not yet, include semiconductor device elements.

Spatially relative terms are used herein to describe the relationships between elements, such as the relationships between substrates, heat-generating devices, cooling assembly components, device packaging components, and other features described below. Unless the relationship is otherwise defined, terms such as “above,” “over,” “upper,” “upwardly,” “outwardly,” “on,” “below,” “under,” “beneath,” “lower,” “top,” “bottom” and the like are generally made with reference to the X, Y, and Z directions set forth by X, Y and Z axis in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements. Furthermore, the term “horizontal” is generally made with reference to the X-axis direction and the Y-axis direction set forth in the drawings. The term “vertical” is generally made with reference to the Z-axis direction set forth in the drawings.

Various embodiments disclosed herein include bonded structures in which two or more elements are directly bonded to one another without an intervening adhesive (referred to herein as “direct bonding”, or “directly bonded”). In some embodiments, direct bonding includes the bonding of a single material on the first of the two or more elements and a single material on a second one of the two or more elements, where the single material on the different elements may or may not be the same. For example, bonding a layer of one inorganic dielectric (e.g. silicon oxide) to another layer of the same or different inorganic dielectric. As discussed in more detail below, the process of direct bonding provides a reduction of thermal resistance between a semiconductor device and a cold plate. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (1st) nonconductive feature directly bonded to another (2nd) nonconductive feature, and ii) at least one (1st) conductive feature directly bonded to another (2″d) conductive feature, without any intervening adhesive. In some hybrid bonding embodiments, there are many 1st conductive features, each directly bonded to a 2nd conductive feature, without any intervening adhesive. In some embodiments, nonconductive features on the first element are directly bond to nonconductive features of the second element at room temperature without any intervening adhesive, which is followed by bonding of conductive features of the first element directly bonded to conductive features of the second element at via annealing at slightly higher temperatures (e.g. >100° C., >200° C., >250° C., >300° C., etc.)

Unless otherwise noted, the terms “cooling assembly” and “integrated cooling assembly” generally refer to a semiconductor device, a cold plate attached to the semiconductor device and/or an opening adaptor attached to the cold plate. In some embodiments, the terms “cooling assembly” and “integrated cooling assembly” may refer to a cold plate attached to an opening adaptor only (i.e., without the semiconductor device). Typically, the cold plate is formed with recessed surfaces that define one or more fluid cavities (e.g., coolant chamber volume(s) or coolant channel(s)) between the cold plate and the semiconductor device. In embodiments where the cold plate is formed with plural fluid cavities, each fluid cavity may be defined by cavity dividers and/or sidewalls of the cold plate. For example, cavity dividers may be spaced apart from each other and extend laterally between opposing cold plate sidewalls (e.g., in one direction between a first pair of opposing cold plate sidewalls, or in two directions between orthogonal pairs of opposing cold plate sidewalls). The cavity dividers and the cold plate sidewalls may collectively define adjacent fluid cavities therebetween. The cold plate may comprise a polymer material. The cold plate may be attached to the semiconductor device by use of a compliant adhesive layer or by direct bonding or hybrid bonding. For example, the cold plate may include material layers and/or metal features which facilitate direct bonding or hybrid bonding with the semiconductor device. Beneficially, the backside of the semiconductor device is directly exposed to coolant fluids flowing through the integrated cooling assembly, thus providing for direct heat transfer therebetween. Unless otherwise noted, the integrated cooling assemblies described herein may be used with any desired fluid, e.g., liquid, gas, and/or vapor-phase coolants, such as water, glycol etc.

Exemplary fluids available for use in the various thermal solution embodiments include: water (either purified or deionized), a glycol (e.g., ethylene glycol, propylene glycol), glycols mixed with water (e.g., ethylene glycol mixed with water (EGW) or propylene glycol mixed with water (PGW)), dielectric fluids (e.g. fluorocarbons, polyalphaolefin (PAO), isoparaffins, synthetic esters, or very high viscosity index (VHVI) oils), or mineral oils. Additionally, depending upon design and operating conditions, these fluids may be used in single-phase liquid, single-phase vapor, two-phase liquid/vapor or two-phase solid/liquid. All of these fluids and fluid mixtures will alter the thermohydraulic and heat transfer properties by altering the temperatures where phase change occurs, as well as meeting design temperature and pressure conditions for the component being cooled or warmed and the thermal solution being deployed. Additionally, multiple combinations of the fluid phases may be employed in various hybrid configurations to meet the particular cooling or warming needs of a respective implementation and still be within the scope of the contemplated embodiments.

Additionally, in some embodiments part or all the cooling is provided by gases. Exemplary gases include atmospheric air and/or one or more inert gases such as nitrogen. Atmospheric air may be taken to mean the mixture of different gases in Earth's atmosphere made up of about 78% nitrogen and 21% oxygen.

Depending on the design needs of a thermal solution system using the disclosed embodiments, engineered dielectric cooling fluids may be used. Some examples of dielectric fluids used for cooling semiconductors include: 3M™ Fluorinert™ Liquid FC-40-A non-flammable, dielectric fluid that can be used in direct contact with live electronics; 3M™ Novec™ Engineered Fluids-A non-flammable, dielectric fluid that can be used in direct contact with live electronics; Galden® PFPE (perfluoropolyether) products used as heat transfer fluids; EnSolv Fluoro HTF-A solvent with a high boiling point and low pour point that can be used for semiconductor wafer cooling. It is understood that in the selection of the cooling fluid, system design aspects such as operating temperatures and pressures, fluid flow rates, fluid viscosity, and other properties will require evaluation when selecting the appropriate cooling fluid.

In some embodiments, the cooling fluids may contain microparticles and/or nanoparticle additives to enhance the conductivity of the cooling fluid within the integrated cooling assemblies. Choi and Eastman (1995) from Argonne National Laboratory, U.S.A. (Yu et al., 2007) coined the word “nanofluid”. Nanofluids are engineered fluids prepared by suspending the nano-sized (1-100 nm) particles of metals/non-metals and their oxide(s) with a base/conventional fluid. The suspension of high thermal conductivity metals/non-metals and their oxides nanoparticles enhances the thermal conductivity and heat transfer ability, etc. of the base fluid. The additives to the underlying cooling fluid may comprise for example, nanoparticles of carbon nanotube, nanoparticles of graphene, or nanoparticles of metal oxides. When the cooling fluid contains microparticles, the microparticles are typically 10 microns or less in diameter. Silicon oxide microparticles may be used.

The volume concentration of these micro or nanoparticles may be less than 1%, less than 0.2%, or less than 0.05%. Depending upon the liquid and micro/nanoparticle type chosen for the cooling fluid, higher volume concentrations of 10% or less, 5% or less, or 2% or less may be used. The cooling fluids may also contain small amounts of glycol or glycols (e.g. propylene glycol, ethylene glycol etc.) to reduce frictional shear stress and drag coefficient in the cooling fluid within the integrated cooling assembly. The availability of different base fluids (e.g., water, ethylene glycol, mineral or other stable oils, etc.) and different nanomaterials provide a variety of nanomaterial options for nanofluid solutions to be used in the various embodiments. These nanomaterial option groups such as aforementioned metals (e.g., Cu, Ag, Fe, Au, etc.), metal oxides (e.g., TiO₂, Al₂O₃, CuO, etc.), carbons (e.g. CNTS, graphene, diamond, graphite . . , etc.), or a mixture of different types of nanomaterials. Metal nanoparticles (Cu, Ag, Au . . . ), metal oxide nanoparticles (Al₂O₃, TiO₂, CuO), and carbon-based nanoparticles are commonly employed elements. Silicon oxide nanoparticles may also be used. Using cooling fluids with micro and/or nanoparticles when practicing the various embodiments disclosed herein can result in increased heat removal efficiencies and effectiveness.

The fluid control design aspects of specific embodiments may require the nanofluids to be magnetic to facilitate either movement or cessation of movement of the fluids within the semiconductor structures. Magnetic nanofluids (MNFs) are suspensions of a non-magnetic base fluid and magnetic nanoparticles. Magnetic nanoparticles may be coated with surfactant layers such as oleic acid to reduce particle agglomeration and/or settling. Magnetic nanoparticles used in MNFs are usually made of metal materials (ferromagnetic materials) such as iron, nickel, cobalt, as well as their oxides such as spinel-type ferrites, magnetite (Fe₃O₄), and so forth. The magnetic nanoparticles used in MNFs typically range in size from about 1 to 100 nanometers (nm).

This disclosure describes embodiments involving the architecture of system and component elements that can be employed to provide for the cooling of semi-conductor components, packaging, and boards. However, those skilled in the art will appreciate the disclosed components and arrangements can be deployed and used in scenarios where component heat up or thermal warm up is desired for a component that is currently outside the low end of the desired operational range. Components that are outside the low end of their operational range can, if started in a cold environment, experience thermal warping or cracking up to and including thermal overexpansion and contact separation that may impair the successful operation of the system. Therefore, in these scenarios, the architectures and embodiments disclosed herein can be used where the indirect thermal solutions supporting them are repurposed or operated in a hybrid configuration to provide warming fluids or heat transfer media to accomplish the warm-up or heat-up scenario. These scenarios are controlled by systems not shown here to bring temperatures up at a speed or timing that enables the materials to avoid the excessive thermal expansion or unequal thermal expansion that may occur among the materials of the semiconductor or packaging being serviced by the thermal solution. Once the component or packaging is brought up into the normal operating range, it can be safely started and brought to a useful operational state.

Considering the warm-up or heat-up embodiments introduced above, the balance of this disclosure and terms used should be viewed in a light that also considers the design option for such warm-up or heat-up. Thus, where terms such as cooling channel, cooling chamber volume, and cooling opening are used, for example, such terms could also be considered as a thermal control channel, a thermal control volume, or a thermal control opening, respectively. A person of skill would understand that heat flux or heat transfer may go in a different direction, but the design concepts are similar and can be successfully employed in the various embodiments.

In some embodiments, a cooling channel is a liquid cooling channel and a liquid may flow through the liquid cooling channel. In some embodiments, the liquid may comprise a water and/or glycol (e.g. propylene glycol, ethylene glycol, and mixtures thereof).

As described below, coolant fluid flowing through a cold plate may be used to control the temperature of semiconductor devices. The fluid flowing across the surface of the semiconductor device absorbs heat and conducts heat away from the semiconductor device.

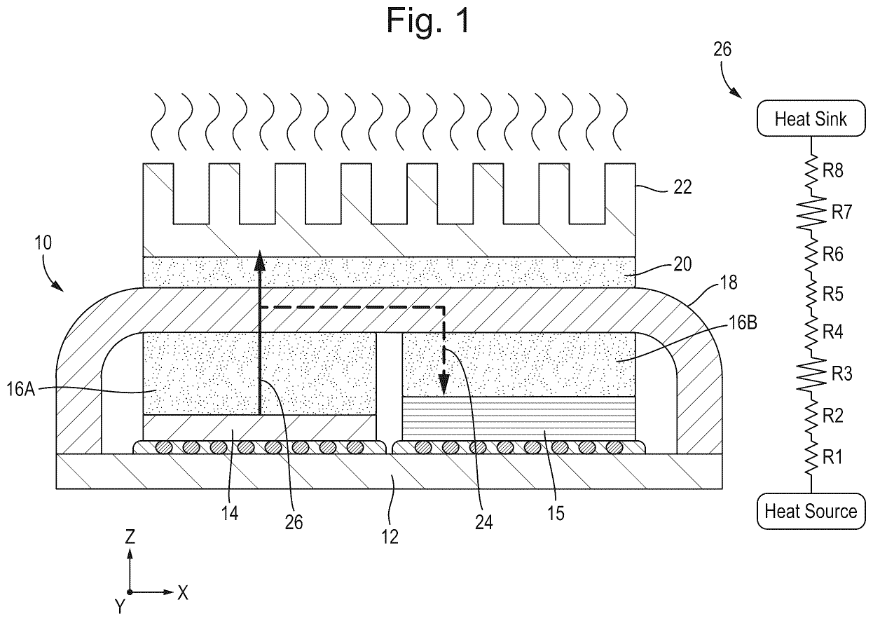

FIG. 1 is a schematic side view of a device package 10 and a heat sink 22 attached to the device package 10. The device package 10 typically includes a package substrate 12, a first device 14, a device stack 15, a heat spreader 18, and first TIM layers 16A, 16B thermally coupling the first device 14 and device stack 15 to the heat spreader 18. The device package 10 is thermally coupled to a heat sink 22 through a second TIM layer 20. The TIM layers 16A, 16B, 20 facilitate thermal contact between components in the device package 10 and between the device package 10 and the heat sink 22.

Unfortunately, as heat flux density increases with increasing power density in advanced semiconductor devices, the cumulative thermal resistance of the system illustrated in FIG. 1 is increasingly problematic as heat cannot be dissipated quickly enough to allow semiconductor devices to run at optimal power. Consequently, the energy efficiency of semiconductor devices is reduced. Furthermore, heat is transferred between semiconductor devices within the device package 10, as shown with heat transfer path 24 (illustrated as a dashed line), where heat may be undesirable transferred from the first device 14 having a high heat flux, such as a CPU or GPU, to the device stack 15 having low heat flux, such as memory, through the heat spreader 18.

For example, as shown in FIG. 1, each device package component and the respective interfacial boundaries therebetween has a corresponding thermal resistance which forms heat transfer path 26 (illustrated by arrow 26 in FIG. 1). The left-hand side of FIG. 1 illustrates the heat transfer path 26 as a series of thermal resistances R1-R8 between a heat source and a heat sink. Here, RI is the thermal resistance of the bulk semiconductor material of the first device 14. R3 and R7 are the thermal resistances of the first TIM layers 16A, 16B and the second TIM layer 20, respectively. R5 is the thermal resistance of the heat spreader 18. R2, R4, R6, and R8 represent the thermal resistance at the interfacial region of the components (e.g., contact resistances). In a typical cooling system, R3 and R7 may account for 80% or more of the cumulative thermal resistance of the heat transfer path 26 and R5 may account for 5% or more. RI of the first device 14 and R2, R4, R6, and R8 of the interfaces account for the remaining cumulative thermal resistance. Accordingly, embodiments herein provide for integrated cooling assemblies embedded within a device package. The embedded cooling assemblies shorten the thermal resistance path between a semiconductor device and a heat sink and reduce thermal communication between semiconductor devices disposed in the same device package, such as described in relation to the figures below.

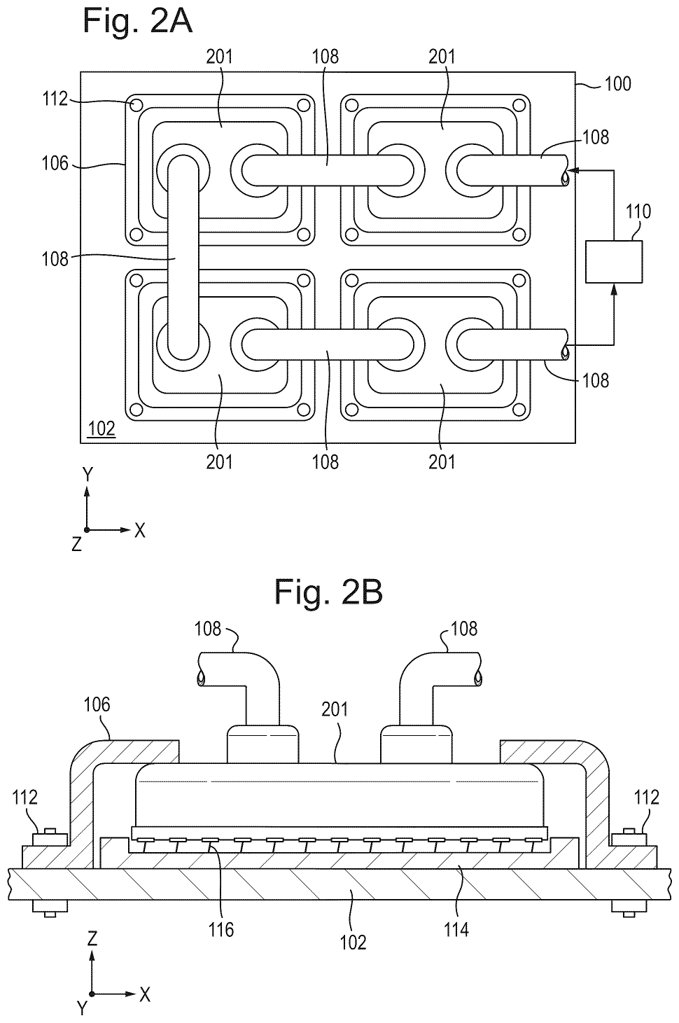

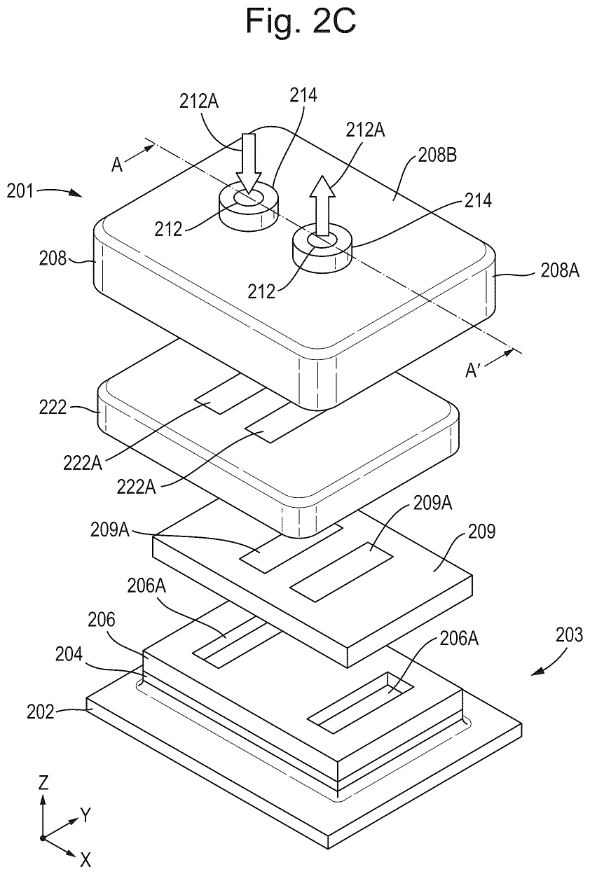

FIG. 2A is a schematic plan view of an example of a system panel 100, in accordance with embodiments of the disclosure. Generally, the system panel 100 includes a printed circuit board, here PCB 102, a plurality of device packages 201 mounted to the PCB 102, and a plurality of coolant lines 108 fluidly coupling each of the device packages 201 to a coolant source 110. It is contemplated that coolant fluid may be delivered to each of the device packages 201 in any desired fluid phase, e.g., liquid, vapor, gas, or combinations thereof and may flow out from each device package 201 in the same phase or a different phase. In some embodiments, the coolant fluid is delivered to the device packages 201 and returned therefrom as a liquid, whereby the coolant source 110 may comprise a heat exchanger or chiller to maintain the coolant fluid at a desired temperature. In other embodiments, the coolant fluid may be delivered to the device packages 201 as a liquid, vaporized to a vapor within the device packages 201, and returned to the coolant source 110 as a vapor. In those embodiments, the device packages 201 may be fluidly coupled to the coolant source 110 in parallel and the coolant source 110 may include or further include a compressor (not shown) for condensing the received vapor to a liquid form.

FIG. 2B is a schematic partial sectional side view of a portion of the system panel 100 of FIG. 2A. As shown, each device package 201 is fluidly coupled to the plurality of coolant lines 108 and is disposed in a socket 114 of the PCB 102 and connected thereto using a plurality of pins 116, or by other suitable connection methods, such as solder bumps (not shown). The device package 201 may be seated in the socket 114 and secured to the PCB 102 using a mounting frame 106 and a plurality of fasteners 112, e.g., compression screws, collectively configured to exert a relatively uniform downward force on the upward facing edges of the device package 201. The uniform downward force ensures proper pin contact between the device package 201 and the socket 114.

FIG. 2C is a schematic exploded isometric view of an example device package 201, in accordance with embodiments of the disclosure. Generally, the device package 201 includes a package substrate 202, an integrated cooling assembly 203 disposed on the package substrate 202, and a package cover 208 disposed on a peripheral portion of the package substrate 202. Suitable materials that may be used in the package cover 208 include copper, aluminum, metal alloys, etc. The package cover 208 extends over the integrated cooling assembly 203 so that the integrated cooling assembly 203 is disposed between the package substrate 202 and the package cover 208. The integrated cooling assembly 203 typically includes a semiconductor device 204, a cold plate 206 bonded to the semiconductor device 204 and an opening adaptor 209. In some embodiments, the cold plate 206 may comprise substrate material like silicon, glass, ceramic, etc. The opening adaptor 209 may comprise material such as metal, silicon glass, ceramic, plastic, etc. In some embodiments, the opening adaptor is attached to the cold plate with a solder. Although the lateral dimensions (or footprint) of the cold plate 206 is shown to be the same or similar to the lateral dimensions (or footprint) of the semiconductor device 204, the footprint of the cold plate 206 may be smaller or larger in one or both directions when compared to the footprint of the semiconductor device 204. The lateral dimensions (or footprint) of the opening adaptor 209 may be substantially the same as the lateral dimensions (or footprint) of the cold plate 206. It should be appreciated that a footprint may be defined as dimensions of the cold plate 206, the semiconductor device 204 and the opening adaptor 209 within a plane, for example X-Y plane in FIG. 2C.

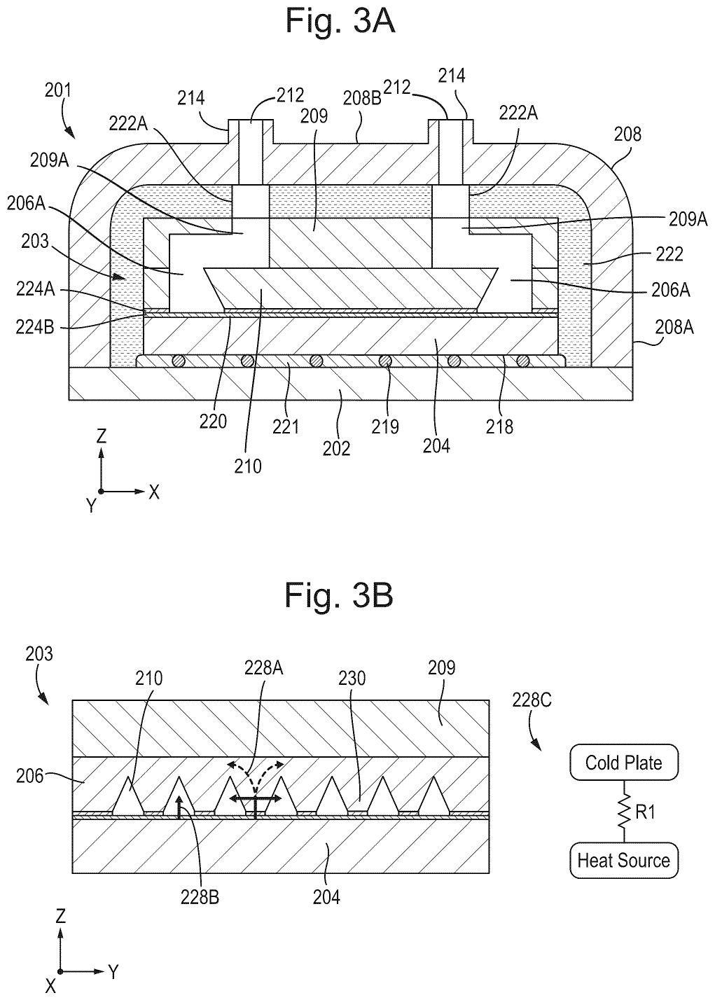

As shown, the device package 201 further includes a sealing material layer 222 that forms a coolant fluid impermeable barrier between the package cover 208 to the integrated cooling assembly 203 that prevents the leaking of the coolant fluid outside of the cooling assembly and prevents coolant fluid from reaching an active side 218 (discussed below in relation to FIG. 3A) of the semiconductor device 204 or outside of the package substrate and causing damage to the semiconductor device or system assembly outside of the package. In some embodiments, the sealing material layer 222 comprises an adhesive material that reliably attaches the package cover 208 to the integrated cooling assembly 203. In some embodiments, the sealing material layer 222 comprises a polymer or epoxy material that extends upwardly from the package substrate 202 to encapsulate and/or surround at least a portion of the semiconductor device 204. In some embodiments, the sealing material layer 222 may also comprise conductive material, e.g. solder. In some embodiments, the sealing material layer 222 is formed from a molding compound, e.g., a thermoset resin, that when polymerized, forms a hermetic seal between the package cover 208 and the cold plate 206. Here, coolant fluid is delivered to the opening adaptor 209 and the cold plate 206 through openings 222A disposed through the sealing material layer 222. As shown, the openings 222A are respectively in registration and fluid communication with inlet and outlet openings 212 of the package cover 208 thereabove and inlet and outlet openings 209A of the opening adaptor 209 therebelow. Turning to the opening adaptor 209, the opening adaptor 209 comprises inlet and outlet openings 209A on a first side facing the package cover 208 and inlet and outlet chamber volumes (not shown) on a second side opposite the first side. The inlet and outlet openings 209A on the first side of the opening adaptor 209 are respectively in registration and fluid communication with inlet and outlet openings 222A of the sealing material layer 222 thereabove. The inlet and outlet chamber volumes on the second side of the opening adaptor 209 are respectively in registration and fluid communication with inlet and outlet openings 206A in the cold plate 206 therebelow.

Generally, the package substrate 202 includes a rigid material, such as an epoxy or resin-based laminate, that supports the integrated cooling assembly 203 and the package cover 208. The package substrate 202 may include conductive features disposed in or on the rigid material that electrically couple the integrated cooling assembly 203 to a system panel, such as the PCB 102.

FIG. 3A is a schematic sectional view in the X-Z plane of the device package 201 taken along line A-A′ of FIG. 2C. As illustrated in FIG. 3A, the semiconductor device 204 includes the active side 218 that includes device components, e.g., transistors, resistors, and capacitors, formed thereon or therein, and a non-active side, here the semiconductor device backside 220, opposite the active side 218. As shown, the active side 218 is positioned adjacent to and facing towards the package substrate 202. The active side 218 may be electrically connected to the package substrate 202 by use of conductive bumps 219, which are encapsulated by a first underfill layer 221 disposed between the semiconductor device 204 and the package substrate 202. The first underfill layer 221 may comprise a cured polymer resin or epoxy, which provides mechanical support to the conductive bumps 219 and protects against thermal fatigue. In some embodiments, the active side 218 may be electrically connected to another package substrate, another active die, or another passive die (e.g. interposer) using hybrid bonding or conductive bumps 219. The cold plate 206 may be disposed above the package substrate 202 with the semiconductor device 204 disposed therebetween. For example, the semiconductor device 204 (and the first underfill layer 221) may be disposed between the cold plate 206 and the package substrate 202. In some embodiments, the cold plate 206 may be disposed directly on the package substrate 202.

In some embodiments, the backside 220 of the semiconductor device 204 comprises a corrosion protective layer (not shown). The corrosion protective layer may be a continuous layer disposed across the entire backside 220 of the semiconductor device 204, such that the cold plate 206 is attached thereto. Beneficially, the corrosion protective layer provides a corrosion resistant barrier layer, thus preventing undesired corrosion of the semiconductor device 204 (e.g., the semiconductor substrate material which might otherwise be in direct contact with coolant fluid flowing through a coolant channel 210).

The cold plate may include one or more coolant channels. The coolant channels may extend between a single inlet opening and a single outlet opening of the cold plate 206, such that the coolant channel(s) share the same inlet and outlet openings. In some embodiments, multiple inlet and/or outlet openings may be coupled to the coolant chamber volume(s).

In embodiments having plural coolant channels, each coolant channel may be connected between a separate inlet opening and a separate outlet opening. In such embodiments, coolant fluid may be directed to the separate inlet openings and from the separate outlet openings using a manifold disposed above the openings in the Z-axis direction.

In some embodiments, a height in the Z-axis direction of the coolant channel(s) may be greater than 100 μm, 100 μm-1000 μm, or 100 um-700 um. A width in the Y-axis direction of the coolant channel(s) may be greater than 100 μm, 100 μm-1000 μm, or 100 um-700 μm. For example, the width of the coolant channel(s) may be greater than the height. A cross-section of the coolant channel(s) in the Y-Z plane is wide enough to allow for a pressure drop of 0-20 psi, 3-15 psi, 4-10 psi.

In some embodiments, preparing a desired surface roughness of the sidewalls of the coolant channels may include depositing an organic layer on a photoresist layer after cold plate features have been etched to form a micromasking layer, such as between 1 to 30 nm. The micromasking layer may be dry etched to form the desired surface roughness, such as between 0.1 to 3.0 nm.

With reference to FIG. 3A, the cold plate 206 is attached to the backside 220 of the device 204 without the use of an intervening adhesive, e.g., the cold plate 206 may be directly bonded to the backside 220 of the device 204, such that the cold plate 206 and the backside 220 of the device 204 are in direct contact. For example, in some embodiments, one or both of the cold plate 206 and the backside 220 of the semiconductor device 204 may comprise a dielectric material layer, e.g., a first dielectric material layer 224A and a second dielectric material layer 224B respectively, and the cold plate 206 is directly bonded to the backside 220 of the semiconductor device 204 through bonds formed between the dielectric material layers 224A, 224B. In some embodiments, one of the cold plate 206 or the backside 220 of the semiconductor device 204 may comprise a thin bonding dielectric layer (e.g. silicon nitride, etc.) and other element(s) may not include any such explicit bonding dielectric layer (or can have only native oxide layer). Here, the first and second dielectric material layers 224A, 224B are illustrated as continuous layers, but it will be understood that one or both of the layers may not be continuous. For example, the first dielectric material layer 224A may be disposed only on lower surfaces of the cold plate 206 facing the backside 220 of the semiconductor device 204. With reference to FIG. 3B, described below, portions of the first dielectric material layer 224A may be disposed only on lower surfaces of support features 230. Beneficially, directly bonding the cold plate 206 to the semiconductor device 204, as described above, reduces the thermal resistance therebetween and increases the efficiency of heat transfer from the semiconductor device 204 to the cold plate 206.

The cold plate 206 may comprise the coolant channels 210 which may extend laterally between the inlet and outlet openings 206A of the cold plate 206 in Z-Y plane. The coolant channels 210 may comprise a trapezoid shape in the X-Z plane.

The opening adaptor 209 may be directly bonded to the cold plate 206, such that the opening adaptor 209 and the cold plate 206 are in direct contact. For example, in some embodiments, one or both of the opening adaptor 209 and the cold plate 206 may comprise a dielectric material layer and the opening adaptor 209 is directly bonded to the cold plate 206 through bonds formed between the dielectric material layers. In some embodiments, one of the opening adaptor 209 or the cold plate 206 may comprise a thin bonding dielectric layer (e.g. silicon nitride, etc.) and other element(s) may not include any such explicit bonding dielectric layer (or can have only native oxide layer).

FIG. 3B is a schematic sectional view in the Y-Z plane of the integrated cooling assembly 203. In FIG. 3B, the cold plate 206 comprises a patterned side that faces towards the semiconductor device 204 and an opposite side that faces towards the opening adaptor 209. The patterned side comprises the plural coolant channels 210, which extend laterally between the inlet and outlet openings 206A of the cold plate 206. Each coolant channel 210 comprises cavity sidewalls which define a corresponding coolant channel 210 therebetween. Portions of the cold plate 206 between the cavity sidewalls form support features 230.

With reference to FIGS. 3A and 3B, a cross-section in the X-Z plane of the coolant channels 210 may be a triangular. The coolant channels 210 may in some examples take a trapezoid shape in the X-Z plane. The coolant channels 210 having a triangular cross-section may present an advantage over coolant chamber volumes having a trapezoidal cross-section because an increased number of coolant channels 210 having triangular cross-sections may be accommodated in a cold plate 206 as compared to coolant chamber volumes having a trapezoidal cross-section, giving rise to a greater perimeter of coolant channels 210, and therefore a greater surface area available for a cooling interface between a semiconductor device 204 and a coolant in the coolant channel 210.

The support features 230 may extend to the backside 220 of the semiconductor device 204 and take a trapezoid shape in the X-Z plane. The support features 230 provide structural support to the integrated cooling assembly 203 and disrupt laminar fluid flow at the interface of the coolant and the device backside 220, resulting in increased heat transfer therebetween. Furthermore, by introducing plural coolant channels 210 to define separate coolant flow paths, an internal surface area of the cold plate 206 is increased, which further increases the efficiency of heat transfer. It can be seen that a lower surface of the support features 230 are in thermal contact with the backside of the semiconductor device 204 so that heat may transfer away from the semiconductor device 204 to the body of the support features 230 and the cold plate 206.

In FIG. 3B, arrows 228A and 228B illustrate two different heat transfer paths in the integrated cooling assembly 203. A first heat transfer path illustrated by arrow 228B shows heat generated by the semiconductor device 204 transferring directly from the semiconductor material of the semiconductor device 204 to coolant fluid flowing through the cold plate 206. A second heat transfer path illustrated by arrows 228A shows heat generated by the semiconductor device 204 being transferred from semiconductor material (e.g., silicon material) of the semiconductor device 204 to semiconductor material (e.g., silicon material) of the cold plate 206 structure, propagated throughout the semiconductor material of the cold plate 206 structure (shown as dashed lines), and being transferring into coolant fluid flowing through the cold plate 206. A thermal resistance of the first and second heat transfer paths 228A, 228B is illustrated by heat transfer path 228C, which is shown as thermal resistance RI between a heat source and a cold plate. Here, RI is the thermal resistance of the bulk semiconductor material of the semiconductor device 204. It can be seen that the heat transfer path 228C of the integrated cooling assembly 203 is reduced compared to the heat transfer path 26 of the device package 10 of FIG. 1, due to the direct bonding discussed above.

In some embodiments, the cold plate 206 may be attached to the semiconductor device 204 using a hybrid bonding technique, where bonds are formed between the dielectric material layers 224A, 224B and between metal features, such as between first metal pads and second metal pads, disposed in the dielectric material layers 224A, 224B.

Suitable dielectrics that may be used as the dielectric material layers 224A, 224B include silicon oxides, silicon nitrides, silicon oxynitrides, silicon carbon nitrides, metal-oxides, metal-nitrides, silicon carbide, silicon oxycarbides, silicon oxycarbonitride, diamond-like carbon (DLC), or combinations thereof. In some embodiments, one or both of the dielectric material layers 224A, 224B are formed of an inorganic dielectric material, e.g., a dielectric material substantially free of organic polymers. Typically, one or both of the dielectric layers are deposited to a thickness greater than the thickness of a native oxide, such as about 1 nanometer (nm) or more, 5 nm or more, 10 nm or more, 50 nm or more, or 100 nm or more. In some embodiments, one or both of the layers are deposited to a thickness of 3 micrometer or less, 1 micrometer or less, 500 nm or less, such as 100 nm or less, or 50 nm or less. The dielectric layer material and thickness may be optimized for lower thermal resistance between the die and the cold plate.

The cold plate 206 may be formed of any suitable material that has sufficient structural strength to withstand the desired pressures of coolant flowing into the coolant chamber volume 210. For example, the cold plate 206 may be formed of semiconductor material like silicon or other engineered materials like glass. In other examples, the cold plate 206 may be formed of a material selected from a group comprising polymers, metals, ceramics, or composites thereof. In some embodiments, the cold plate 206 may be formed of stainless steel (e.g., from a stainless steel metal sheet) or a sapphire plate.

In some embodiments, the cold plate 206 may be formed of a bulk material having a substantially similar coefficient of linear thermal expansion (CTE) to the bulk material of the substrate 202, where the CTE is a fractional change in length of the material (in the X-Y plane) per degree of temperature change. In some embodiments, the CTEs of the cold plate 206 and the substrate 202 are matched so that the CTE of the substrate 202 is within about +/−20% or less of the CTE of the cold plate 206, such as within +/−15% or less, within +/−10% or less, or within about +/−5% or less when measured across a desired temperature range. In some embodiments, the CTEs are matched across a temperature range from about −60° C. to about 100° C. or from about-60° C. to about 175° C. In one example embodiment, the matched CTE materials each include silicon.

In some embodiments, the cold plate 206 may be formed of a material having a substantially different CTE from the semiconductor device 204, e.g., a CTE mismatched material. In such embodiments, the cold plate 206 may be attached to the semiconductor device 204 by a compliant adhesive layer (not shown) or a molding material that absorbs the difference in expansion between the cold plate 206 and the semiconductor device 204 across repeated thermal cycles.

The package cover 208 generally comprises one or more vertical or sloped sidewall portions 208A and a lateral portion 208B that spans and connects the sidewall portions 208A. The sidewall portions 208A may extend upwardly from a peripheral surface of the package substrate 202 to surround the device 204, the cold plate 206 disposed thereon and the opening adaptor 209. The lateral portion 208B may be disposed over the opening adaptor 209 and is typically spaced apart from the opening adaptor 209 by a gap corresponding to the thickness of the sealing material layer 222. Coolant is circulated through the coolant chamber volume 210 through the inlet and outlet openings 212 of the package cover 208 formed through the lateral portion 208B. The inlet and outlet openings 209A of the opening adaptor 209 may be in fluid communication with the inlet and outlet openings 212 of the package cover 208 through the inlet and outlet openings 222A formed in the sealing material layer 222 disposed therebetween. In certain embodiments, coolant lines 108 (FIGSs. 2A-2B) may be attached to the device package 201 by use of connector features formed in the package cover 208, such as threads formed in the sidewalls of the inlet and outlet openings 212 of the package cover 208 and/or protruding features 214 that surround the inlet and outlet openings 212 and extend upwardly from a surface of the lateral portion 208B.

Typically, the package cover 208 is formed of semi-rigid or rigid material so that at least a portion of the downward force exerted on the package cover 208 by the mounting frame is transferred to a supporting surface of the package substrate 202 and not transferred to the cold plate 206 and the semiconductor device 204 therebelow. In some embodiments, the package cover 208 is formed of a thermally conductive metal, such as aluminum or copper. In such embodiments, the package cover 208 functions as a heat spreader that redistributes heat from one or more electronic components of the semiconductor device 204.

It should be noted that the direction in which coolant fluid flows through the cold plate 206 may be controlled depending on the relative locations of the inlet and outlet openings. For example, coolant fluid may flow from left to right in the device package 201 of FIG. 3A when the inlet openings 212, 222A, 206A, 209A of the package cover 208, the sealing material layer 222, the cold plate 206, and the opening adaptor 209, respectively, are located on the left-hand side of the device package 201 and the outlet openings 212, 222A, 206A, 209A of the package cover 208, the sealing material layer 222, the cold plate 206, and the opening adaptor 209 respectively, are located on the right-hand side of the device package 201. Alternatively, coolant fluid may flow from right to left in the device package 201 illustrated in FIG. 3A when the outlet openings 212, 222A, 206A, 209A of the package cover 208, the sealing material layer 222, the cold plate 206, and the opening adaptor 209 are located on the left-hand side of the device package 201 and the inlet openings 212, 222A, 206A, 209A of the package cover 208, the sealing material layer 222, the cold plate 206, and the opening adaptor 209 are located on the right-hand side of the device package 201. Although only one set of inlet and outlet openings are shown and described here, additional inlet and outlet openings may also be provided at various locations on the package cover 208, the sealing material layer 222, the cold plate 206 and the opening adaptor 209.

With reference to FIG. 3A, an example flow path of the coolant fluid through the coolant chamber volume 210 may be as follows:
1. Coolant fluid enters the coolant chamber volume 210 through the inlet openings.
2. Coolant fluid flows across the inside surfaces of the cold plate 206 and absorbs heat generated by the semiconductor device 204 which has dissipated into the cold plate 206 structure. The coolant fluid may also flow directly across the backside 220 of the semiconductor device 204 to absorb heat energy directly from the semiconductor device 204. Various coolant channels may be formed to direct the coolant fluid flow from inlet opening(s) to outlet opening(s) and facilitate heat extraction from the semiconductor device 204 by the coolant fluid. In some embodiments, the coolant fluid may be in direct contact with the backside 220 of the semiconductor device 204 or via one or more substrate or layers between the coolant fluid or backside 220 of the semiconductor device 204.
3. Coolant fluid exits the coolant chamber volume 210 through outlet openings. It will be understood from the above flow path that heat is extracted without introducing an unnecessary thermal resistance (such as, for example, a TIM disposed between the backside 220 of the semiconductor device 204 and the cold plate 206) between the backside 220 of the semiconductor device 204 and the cold plate 203.

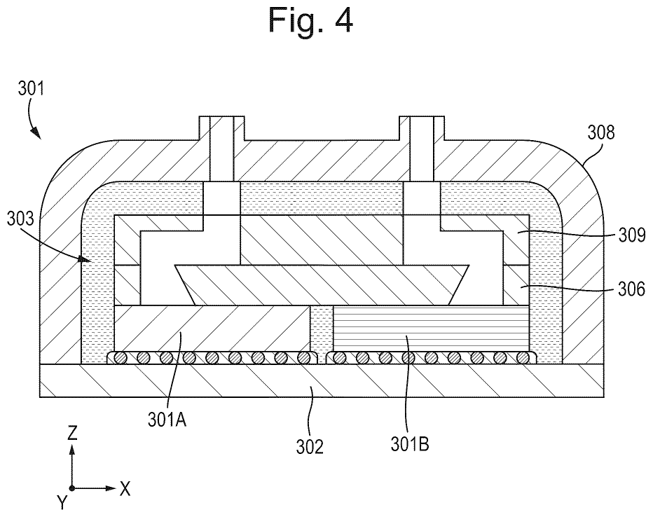

FIG. 4 is a schematic side sectional view in the X-Z plane of an example of a multi-component device package 301 that includes a cold plate 306 directly bonded to the backside surfaces of two or more devices 301A, 301B and an opening adaptor 309 attached to the cold plate 306. The multi-component device package 301 may be similar to the device package 201 described above, and therefore the description of similar features is omitted for brevity. In some embodiments, the two or more devices 301A and 301B are reconstituted and then bonded to the cold plate 306. As shown, the device package 301 includes a package substrate 302, an integrated cooling assembly 303 and a package cover 308. The integrated cooling assembly 303 may include a plurality of devices 301A (one shown) which may be singulated and/or disposed in a vertical device stack 301B (one shown). The cold plate 306 may be attached to each of the devices 301A and device stack 301B, e.g., by the direct bonding methods described herein or other method including flip chip bonding, etc. In some embodiments, the device 301A may comprise a processor and the device stack 301B may comprise a plurality of memory devices. Here, the device 301A and the device stack 301B are disposed in a side-by-side arrangement on the package substrate 302 and are in electrical communication with one another through conductive elements formed in, on, or through the package substrate 302. Here, the cold plate 306 is sized to provide a bonding surface for attachment to both the device 301A and the device stack 301B but may otherwise be the same or substantially similar to other cold plates described herein. In some embodiment, the lateral dimensions (or footprint) of the cold plate 306 may be smaller or larger than the combined lateral dimensions (or footprint) of both the device 301A and the device stack 301B. The lateral dimensions (or footprint) of the opening adaptor 309 may be substantially the same as the lateral dimensions (or footprint) of the cold plate 306. In some embodiments, one or more sidewalls of the cold plate 306 may be aligned or offset to the vertical sidewalls of the device 301A and the device stack 301B (including inside or outside their footprint). In some embodiment, more than one cold plate 306 may be bonded. For example, separate cold plates may be bonded to the device 301A and the device stack 301B.

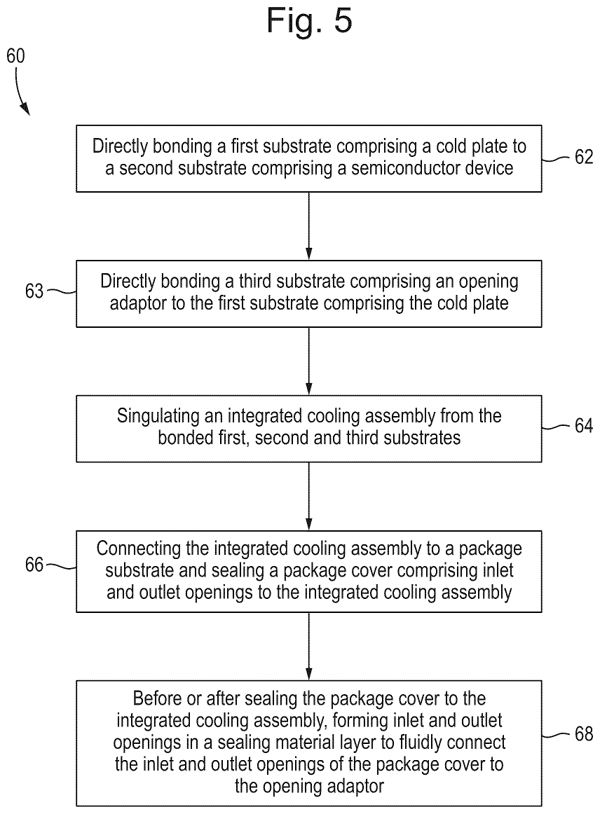

FIG. 5 is a flow diagram setting forth a method 60 of forming an integrated cooling assembly, according to embodiments of the disclosure. Generally, the method includes bonding a first substrate comprising one or more cold plates 206 to a second substrate comprising one or more semiconductor devices 204. The method may further include bonding a third substrate comprising an opening adaptor 209 to the first substrate comprising the cold plate 206. The method may further comprise singulating one or more integrated cooling assemblies 203 from the bonded first, second and third substrates.

It will be understood that the first substrate may be a cold plate die or part of a wafer of cold plates. Further, the second substrate may be a semiconductor device die or part of a wafer of semiconductor devices 204. Further, the third substrate may be an opening adaptor die or part of a wafer of opening adaptors 209. Therefore, the method 60 may include die-to-die direct bonding (e.g., cold plate die to semiconductor device die and/or cold plate die to opening adaptor die), wafer-to-die direct bonding (e.g., cold plate die to semiconductor device wafer, or cold plate wafer to semiconductor device die, cold plate die to opening adaptor wafer, or cold plate wafer to opening adaptor die), and wafer-to-wafer direct bonding (e.g., cold plate wafer to semiconductor device wafer, cold plate wafer to opening adaptor wafer). It will be understood that the singulation step (discussed in relation to block 64, below) may not be required for a die-to-die direct bonding operation.

For simplicity, the following description is focused on forming one integrated cooling assembly 203 comprising one cold plate 206, one semiconductor device 204 and one opening adaptor 209. However, as mentioned above, in some embodiments, the first substrate may comprise plural cold plates 206, the second substrate may comprise plural semiconductor devices 204, and the third substrate may comprise plural opening adaptors 209, such that plural integrated cooling assemblies 203 may be formed from the first, second and third substrates.

At block 62, the method 60 includes directly bonding the first substrate (e.g., a monocrystalline silicon wafer) comprising a cold plate 206 to the second substrate (e.g., a monocrystalline silicon wafer) comprising a semiconductor device 204 without an intervening adhesive.

In some embodiments, the first substrate may be etched using a patterned mask layer formed on its surface to form features of the cold plate 206. An anisotropic etch process may be used, which uses inherently differing etch rates for the silicon material as between {100} plane surfaces and {111} plane surfaces when exposed to an anisotropic etchant.

In some embodiments, the etching process is controlled to where the etch rates of the substrate surfaces have a ratio between about 1:10 and about 1:200, such as between about 1:10 and about 1:100, for example between about 1:10 and 1:50, or between about 1:25 and 1:75. Examples of suitable anisotropic wet etchants include aqueous solutions of potassium hydroxide (KOH), ethylene diamine and pyrocatechol (EPD), ammonium hydroxide (HN₄OH), hydrazine (N₂H₄), or tetra methyl ammonium hydroxide (TMAH). The actual etch rates of the silicon substrate depend on the concentration of the etchant in the aqueous solution, the temperature of the aqueous solution, and a concentration of the dopant in the substrate (if any). Typically, the mask layer is formed of a material which is selective to anisotropic etch compared to the underlying monocrystalline silicon substrate. Examples of suitable mask materials include silicon oxide (SixO;) or silicon nitride (SixNy). In some embodiments, the mask layer has a thickness of about 100 nm or less, such as about 50 nm or less, or about 30 nm or less. The mask layer may be patterned using any suitable combination of lithography and material etching patterning methods.

The second substrate may include a bulk material, and a plurality of material layers disposed on the bulk material. The bulk material may include any semiconductor material suitable for manufacturing semiconductor devices, such as silicon, silicon carbide, silicon germanium, germanium, group III-V semiconductor materials, group II-VI semiconductor materials, or combinations thereof. While some high-performance processors like central processing units (CPUs), graphics processing units (GPUs), neural processing units (NPUs), and tensor processing units (TPUs) are typically made out of silicon, some other high power density (hence substantial heat generating) devices may comprise silicon carbide or gallium nitride, for example. In some embodiments, the second substrate may include a monocrystalline wafer, such as a silicon wafer, a plurality of device components formed in or on the silicon wafer, and a plurality of interconnect layers formed over the plurality of device components. In other embodiments, the second substrate may comprise a reconstituted substrate, e.g., a substrate formed from a plurality of singulated devices embedded in a support material. In some embodiments, each semiconductor device may have its own individual cold plate fabricated through a reconstitution process.

The bulk material of the second substrate may be thinned after the semiconductor device 204 is formed using one or more backgrinding, etching, and polishing operations that remove material from the backside. Thinning the second substrate may include using a combination of grinding and etching processes to reduce the thickness (in the Z-direction) to about 450 μm or less, such as about 200 μm or less, or about 150 μm or less or about 50 μm or less. After thinning, the backside 220 may be polished to a desired smoothness using a chemical mechanical polishing (CMP) process, and the dielectric material layer may be deposited thereon. In some embodiments, the dielectric material layer may be polished to a desired smoothness to prepare the second substrate for the bonding process. In some embodiments, the method 60 includes forming a plurality of metal features in the dielectric material layer in preparation for a hybrid bonding process, such as by use of a damascene process.

In some embodiments, the active side of the second substrate is temporarily bonded to a carrier substrate (not shown) before or after the thinning process. When used, the carrier substrate provides support for the thinning operation and/or for the thinned material to facilitate substrate handling during one or more of the subsequent manufacturing operations described herein.

Here, the method 60 may include forming dielectric layers on one or both the first and second substrates, and directly bonding includes forming dielectric bonds between a first dielectric material layer of the first substrate and a second dielectric material layer of the second substrate (or forming dielectric bonds between one substrate and a dielectric material layer of the other substrate). Direct bonding processes join dielectric layers by forming strong chemical bonds (e.g., covalent bonds) between the dielectric layers.

Generally, directly bonding the surfaces (of the dielectric material layers formed on the first and second substrates) includes preparing, aligning, and contacting the surfaces. Examples of dielectric material layers include silicon oxide, silicon nitride, silicon oxynitride, and silicon carbonitride. Preparing the surfaces may include smoothing the respective surfaces to a desired surface roughness, such as between 0.1 to 3.0 nm RMS, activating the surfaces to weaken or open chemical bonds in the dielectric material, and terminating the surfaces with a desired species. Smoothing the surfaces may include polishing the first and second substrates using a CMP process. Activating and terminating the surfaces with a desired species may include exposing the surfaces to radical species formed in a plasma. The bond interface between the bonded dielectric layers can include a higher concentration of materials from the activation and/or last chemical treatment processes compared to the bulk of the bonding layers. For example, some embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen concentration peak can be formed at the bond interface between non-conductive bonding surfaces.

In some embodiments, the plasma is formed using a nitrogen-containing gas, e.g., N₂, and the terminating species includes nitrogen, or nitrogen and hydrogen. In some embodiments, fluorine may also be present within the plasma. In some embodiments, the surfaces may be activated using a wet cleaning process, e.g., by exposing the surfaces to an aqueous ammonia solution. In some embodiments, the dielectric bonds may be formed using a dielectric material layer deposited on only one of the first and second substrates, but not on both. In those embodiments, the direct dielectric bonds may be formed by contacting the deposited dielectric material layer of one of the first and second substrates directly with a bulk material surface (or such a surface with a native oxide) of the other substrate.

Directly forming direct dielectric bonds between the first and second substrates at block 62 may include bringing the prepared and aligned surfaces into direct contact at a temperature less than 150° C., such as less than 100° C., for example, less than 30° C., or about room temperature, e.g., between 20° C. and 30° C. Without intending to be bound by theory, in the case of directly bonding surfaces terminated with nitrogen and hydrogen (e.g., NH2 groups), it is believed that the hydrogen terminating species diffuse from the interfacial bonding surfaces, and chemical bonds are formed between the remaining nitrogen species during the direct bonding process. In some embodiments, the direct bond is strengthened using an anneal process, where the substrates are heated to and maintained at a temperature of greater than about 30° C. and less than about 450° C., for example, greater than about 50° C. and less than about 250° C., or about 150° C. for a duration of about 5 minutes or more, such as about 15 minutes. Typically, the bonds will strengthen over time even without the application of heat. Thus, in some embodiments, the method does not include heating the substrates.

In embodiments where the first and second substrates are bonded using hybrid dielectric and metal bonds, the method 60 may further include planarizing or recessing the metal features below the dielectric field surface before contacting and bonding the dielectric material layers. After the dielectric bonds are formed, the first and second substrates may be heated to a temperature of 150° C. or more and maintained at the elevated temperature for a duration of about 1 hour or more, such as between 8 and 24 hours, to form direct metallurgical bonds between the metal features.

Suitable direct dielectric and hybrid bonding technologies that may be used to perform aspects of the methods described herein include ZiBond® and DBIR, each of which are commercially available from Adeia Holding Corp., San Jose, CA, USA.

At block 63, the method 60 includes directly bonding the third substrate (e.g., a monocrystalline silicon wafer, glass, etc.) comprising an opening adaptor 209 to the first substrate (e.g., a monocrystalline silicon wafer, glass, etc.) comprising the cold plate 206 without an intervening adhesive. The bonding between the third substrate and first substrate may be similar to the bonding between the first substrate and the second substrate described above, and therefore the description is omitted for brevity.

At block 64, the method 60 includes singulating at least one integrated cooling assembly 203 from the bonded first, second and third substrates. Singulation after bonding may impart distinctive structural characteristics on the integrated cooling assembly 203 as the bonding surface of the cold plate 206 has the same perimeter as the backside of the semiconductor device 204 bonded thereto. Thus, the sidewalls (e.g., side surfaces) of the cold plate 206 and the opening adapter 209 are typically flush with the edges (e.g., side surfaces) of the semiconductor device 204 about their common perimeters. In some embodiments, the cold plate 206 is singulated from the first substrate using a process that cuts or divides the first substrate in a vertical plane, i.e., in the Z-direction. In those embodiments, the side surfaces of the cold plate 206 are substantially perpendicular to the backside 220 of the semiconductor device 204, i.e., a horizontal (X-Y) plane of an attachment interface between the semiconductor device 204 and the cold plate 206. In some embodiments, the cold plate 206 is singulated using a saw or laser dicing process. The opening adaptor 209 may be singulated from the third substrate in a similar manner to the manner in which the cold plate 206 is singulated from the first substrate.

At block 66, the method may include connecting the integrated cooling assembly 203 to the package substrate 202 and sealing a package cover 208 comprising inlet and outlet openings 212 to the integrated cooling assembly 203 by use of a molding compound that when cured, forms a sealing material layer 222.

At block 68, the method 60 may include, before or after sealing the package cover 208 to the integrated cooling assembly 203, forming inlet and outlet openings 222A in the sealing material layer 222 to fluidly connect the inlet and outlet openings 212 of the package cover 208 to the opening adaptor 209.

In another embodiment, an integrated cooling assembly may only comprise a cold plate 206 and an opening adaptor 209. Such integrated cooling assembly may be formed by bonding a first substrate comprising one or more cold plates 206 to a second substrate comprising an opening adaptor 209. The method may further comprise singulating one or more integrated cooling assemblies 203 from the bonded first and second.

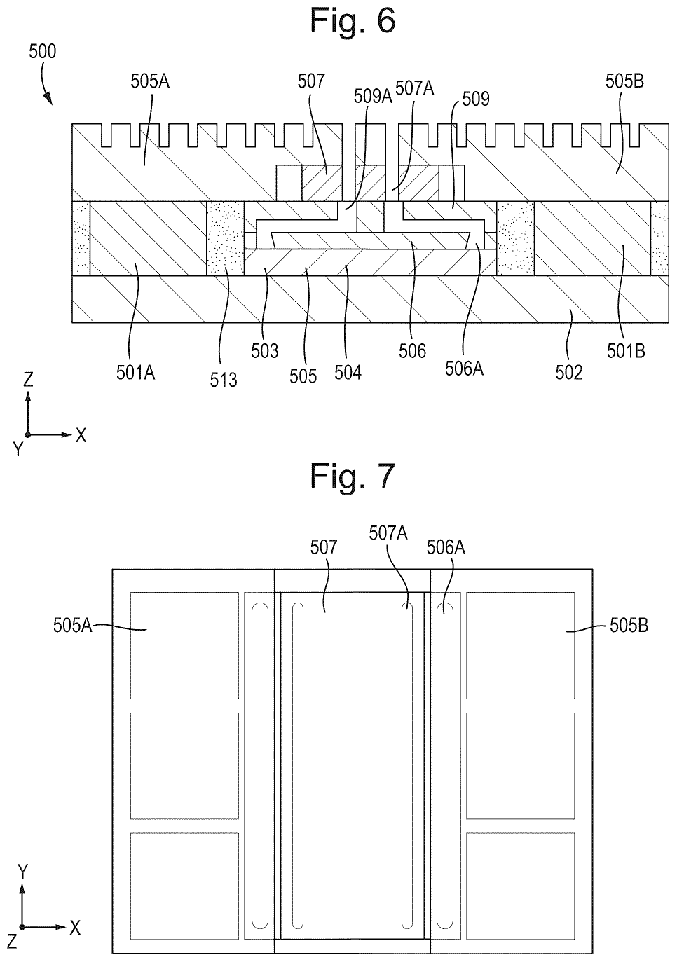

FIG. 6 is a cross-sectional view of a device package according to one or more embodiments. The device package 500 may comprise a first low power density (or thermal density) region 501A and a second low power density (or thermal density) region 501B located at sides thereof and a high power density (or thermal density) region 503 located at a centre thereof. It should be noted that the terms low power density and high power density are relative to one another and are not intended to be limiting regarding a specific power dissipation of any region. In some embodiments, the first and/or the second low power density regions 501A, 501B may comprise at least one relatively low power electronic component such as High Bandwidth Memory (HBM) and/or a dummy die. A dummy die may comprise a non-operational die, filler (encapsulant) material, a portion of a reconstituted wafer, a blank carrier, and/or the like. The high power density region 503 may comprise at least one relatively high power electronic component such as a Graphical Processing Unit (GPU), Central Processing Unit (CPU), Neural Processing unit (NPU), micro-controller unit (MCU), etc. A dielectric or an insulating material (e.g. organic dielectric like silicon oxide or inorganic dielectric like mold compound, resin, epoxy, etc.) or sealing material 513 may be disposed between the electronic components in the high and low power density regions. In some other embodiments, the first and/or the second low power density regions 501A, 501B may be the extensions or peripheral regions of the high power density region 503, In some embodiments, one of the electronic power components may comprise a die stack.

The device package 500 may comprise a package substrate 502, an integrated cooling assembly 505 disposed on the package substrate 502. The integrated cooling assembly 505 may comprise a first semiconductor device 504, a cold plate 506 attached to the first semiconductor device 504 and an opening adaptor 509 attached to the cold plate 506.

The first low power density region 501A may comprise a second semiconductor device disposed horizontally adjacent to the first semiconductor device 504, and a heat sink 505A may be disposed above the second semiconductor device. The heat sink 505A may extend laterally above a portion of the opening adaptor 509.

The second low power density region 501B may comprise a third semiconductor device disposed horizontally adjacent to the first semiconductor device 504. The first semiconductor device 504 may be disposed between the second and third semiconductor devices. A first portion of the heat sink 505A may be disposed above the second semiconductor device and a second portion of the heat sink 505B may be disposed above the third semiconductor device. The first distance may be less than a distance between the first and second portions of the heat sink.

The low power density regions 501A and 501B may be at least partially cooled by using the heat sinks 505A, 505B disposed thereon respectively and the high power density region 503 may be cooled by attaching a manifold 507 to the opening adapter 509 and providing a coolant that flows through the opening adaptor 509 to the cold plate 506.

The manifold 507 may be a block with openings 507A. The heat sinks 505A, 505B may extend over the manifold 507 and the manifold 507 may bridge a gap between the heat sinks 505A, 505B and the opening adaptor 509. This may allow for a fluid connection to the opening adaptor 509. The openings 507A of the manifold 507 may comprise the same or different width as the openings 509A of the opening adaptor 509, nonetheless a fluidly sealed connection may be formed between the openings 507A of the manifold 507 and the openings 509A of the opening adaptor 509. The manifold 507 may comprise an epoxy material, a polymer material, a metal material or a silicon based material. The manifold 507 may comprise the same or different material as the opening adaptor 509.

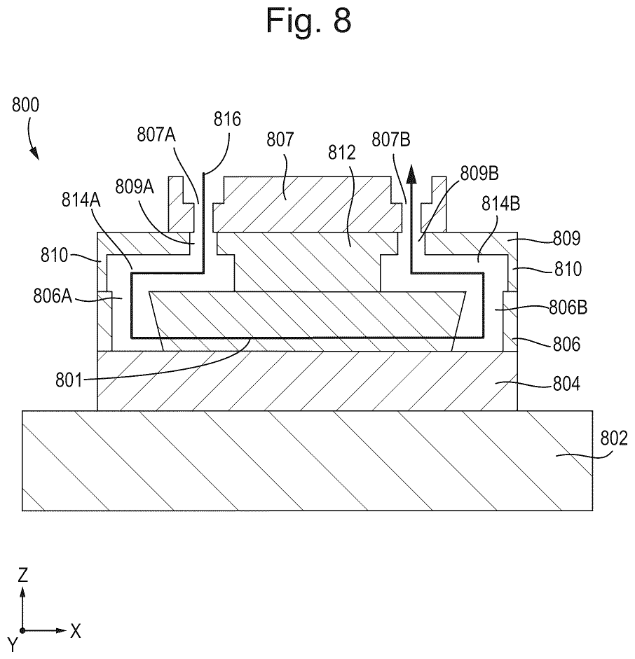

A gap between low power density regions 501A, 501B and the high power density region 503 may be small (for example, between 10-500 um). Consequently, the heat sinks 505A, 505B disposed on the low power density regions 501A, 501B may partially overlap the high power density region 503 as illustrated in FIG. 6. This prohibits inlet and outlet openings of the manifold 507 to be located near a periphery of the the first semiconductor device 504, at which the inlet and outlet openings 507A of the cold plate 506 are located. Consequently, the inlet and outlet openings 507A of the manifold 507 are misaligned with the inlet and outlet openings 506A of the cold plate 506. Advantageously, the opening adaptor 509 may compensate for the misalignment between the inlet and outlet openings 507A of the manifold 507 and the inlet and outlet openings 506A of the cold plate 506 by forming a fluid connection between respective inlets and outlets. The opening adaptor 509 may be similar to the opening adaptor described in the embodiments of FIGS. 8 to 10.

FIG. 7 illustrates a top view of the device package 500 of FIG. 6. In FIG. 7, the manifold 507 is disposed over the first semiconductor device 504. Inlet and outlet openings 506A of the cold plate 506 may span across the first semiconductor device 504 to form an elongated shape (i.e. from one edge of the first semiconductor device 504 to another edge of the first semiconductor device 504) to achieve adequate and/or efficient cooling across the first semiconductor device 504. The inlet and outlet openings 506A of the cold plate 206 comprising an elongated shape may comprise a length and a width in the plane shown in FIG. 7. Although the inlet and outlet openings 506A of the cold plate 206 are shown to be of an elongated shape, any other shape (e.g. circular, oval square, rectangular, hexagonal or any other regular or irregular shapes) may also be possible. The length may be greater than the width and may span across the length of the cold plate 506. The inlet and outlet openings 507A of the manifold 507 may also comprise an elongated shape may which comprises a length and a width in the plane shown in FIG. 7. The length may be greater than the width and may span across the length of the manifold 507. Although in FIG. 7, the length of the inlet and outlet openings 507A of the manifold 507 are shown to be substantially the same as the length of the inlet and outlet openings 506A of the cold plate 206, in other embodiments the lengths may be different. Although only one inlet and outlet opening are shown in FIG. 7, more than one opening of either type may also be present.

In FIG. 7, each of the low power density regions 501A, 501B are shown to comprise three blocks where each of the blocks represent an electronic component or a dummy die, this is merely exemplary and in other embodiments, the low power density regions 501A, 501B may comprise other number of blocks with varying arrangements. In some embodiments, the high power density region 503 may comprise any number of blocks with varying arrangements of electronic components. It should be noted that the low power density regions 501A and 501B, along with openings 506A of the cold plate 506, are obscured by heat sinks 505A and 505B for a top view. These elements are depicted solely in FIG. 7 for illustrative purposes.

In some embodiments, the first semiconductor device may comprise a plurality of integrated circuit dies. The first semiconductor device may be part of a reconstituted wafer. A reconstituted wafer is taken to be a wafer comprising dies, die interconnects, and a dielectric (e.g., organic dielectric (e.g., silicon oxide, silicon nitride, etc.) and/or inorganic dielectrics (e.g., molding compound, resin, etc.). For example, a semiconductor wafer may be singulated into dies, and a dielectric material may be disposed around the dies to form a reconstituted wafer. The dies may be arranged in a layout according to a desired spacing between the dies. Reconstituting dies to form a reconstituted wafer allows dies previously singulated from a wafer to be molded into a new wafer (i.e., a reconstituted wafer).

There exists other arrangement under which a component such as a manifold connecting a cooling system to an integrated cooling assembly cannot permit fluid inlet and outlet locations that match an inlet and outlet location of the integrated cooling assembly. Examples of such arrangements include:
a) For devices with only processor chip liquid cooled (and not peripheral chips like HBM), mounting a manifold may be complicated as it introduces unnecessarily restrictions on the accuracy of Thermal Interface Material (TIM) placement on HBM and a sealant placement for the GPU (sealant for liquid cooling manifold). Thus, the size of the and the location of the openings of the manifold may be adjusted which disadvantageously may result misalignment between the openings of a cold plate and the manifold. b) Large processor dies (CPU, GPU, NPU, MCU, etc.) typically have I/O interfaces (e.g. memory interface, PHYS, etc.) designed at the periphery of the die. This may interfere with the positioning of the openings of a manifold thus creating misalignment between the openings of a cold plate and the manifold.

FIG. 8 illustrates an integrated cooling assembly 800 according to one or more embodiments. The integrated cooling assembly 800 is disposed on a substate 802. The integrated cooling assembly 800 comprises a semiconductor device 804, a cold plate 806 attached to the semiconductor device 804 and an opening adaptor 809 attached to the cold plate 806.

The cold plate 806 comprises one or more coolant channels 801 integrally formed within the cold plate 806. The cold plate 806 further comprises an inlet opening 806A and an outlet opening 806B spaced apart by a first distance. The inlet and outlet openings 806A, 806B may be positioned at opposite sides of the semiconductor device 804, in this manner, a coolant fluid flowing between the inlet and outlet openings 806A, 806B may be in contact with a maximum surface area at the back of the semiconductor device 804. As the first distance is increased (up to a limit of a width of the semiconductor device 804 in the direction of the first distance direction), a thermal extraction from the semiconductor device 804 may be increased. In some embodiments, where the semiconductor device 804 is part of a reconstituted wafer, the first distance may be greater than a width of the semiconductor device 804 in the direction of the first distance.

Coolant may enter and exit the one or more cooling channels 801 through the inlet opening 806A and the outlet opening 806B. The opening adaptor 809 may comprise an inlet opening 809A, an outlet opening 809B, sidewalls 810, and a divider 812 between the sidewalls 810. The sidewalls 810 and the divider 812 of the opening adaptor 809 both extend downwardly to the cold plate 806 to define an inlet chamber volume 814A and an outlet chamber volume 814B therebetween. The divider 812 may extend between two opposing and facing surfaces between the cold plate 806 and the opening adaptor 809 and may form a substantially vertical (along the Z-axis direction in FIG. 3A) wall which prevents inwardly flowing fluid reaching the outlet chamber volume 814B of the opening adaptor 809 and prevents outwardly flowing fluid reaching the inlet chamber volume 814A of the opening adaptor 814A. The inlet and outlet openings 809A, 809B of the opening adaptor 809 are spaced apart by a second distance different from the first distance. The first distance may be greater than the second distance. In some embodiments, the first distance may be between 1 to 10 cm, 1 to 5 cm, or 5 to 10 cm. The second distance may be between 1 to 4 cm, 2 to 9 cm, or 6 to 9 cm. The coolant channel 801 may be in fluid communication with the inlet chamber volume and the outlet chamber volume 814A, 814B via the first and second openings 806A, 806B of the cold plate 806. In some embodiments, the inlet chamber 814A and the outlet chamber 814B may comprise at least one of a length, a width or volume different to one another. For example, the inlet chamber 814A may comprise a volume larger or smaller than that of the outlet chamber 814B or vice versa.

The inlet chamber volume 814A may at least partially overlap and be in fluid communication with the first opening 806A of the cold plate 806. For example, partially overlap may be taken to mean, with reference to FIG. 8, that a portion of the inlet chamber volume 814A is exposed to and is overlapping the inlet opening 806A. Similarly, the outlet chamber volume 814B may at least partially overlap and be in fluid communication with the second opening 806B of the cold plate 806. The inlet chamber volume and an outlet chamber volume 814A, 814B may be separated from the coolant channel 801 by portions of an upper surface of the cold plate 806 surrounding the inlet and outlet openings 806A, 806B of the cold plate 806. For example, the portion of the upper surface of the cold plate 806 may extend laterally underneath and be exposed to the inlet chamber volume and the outlet chamber volume 814A, 814B. Furthermore, the upper surface of the cold plate 806 and sidewalls of the cold plate 806 may collectively define the inlet opening 806A and the outlet opening 806B of the cold plate 806.

The inlet chamber volume 814A may bridge a gap between the inlet opening 807A of the manifold 807 and the inlet opening 806A of the cold plate 806 to allow a fluid flow from the inlet opening 807A of the manifold 807 to the inlet opening 806A of the cold plate 806. The outlet chamber volume 814B may bridge a gap between the outlet opening 807B of the manifold 807 and the outlet opening 806B of the cold plate 806 to allow a fluid flow from the outlet opening 806B of the cold plate 806 to the outlet opening 807B of the manifold 807.

In FIG. 8, arrow 816 illustrates a coolant flow path. A coolant flow path 816 may enter through the inlet opening 807A of the manifold 807, enter the inlet coolant chamber volume 814A through the inlet opening 809A of the opening adaptor 809, enter the coolant channel 801 through the inlet opening 806A of the cold plate 806, travel across the semiconductor device 804 to cool the semiconductor device 804 by absorbing heat, exit the coolant channel 801 through the outlet opening 806B of the cold plate, enter the outlet chamber volume 814B, exit the outlet chamber volume 814B through the outlet opening 809B of the opening adaptor 809 and exit through outlet opening 807B of the manifold 807.

It can be seen that the inlet and outlet openings 807A, 807B of the opening adaptor 807 align with the inlet an outlet openings 807A, 807B of the manifold 807. The opening adaptor 807 thus may compensate for a misalignment between the inlet and outlet opening 806A, 806B of the cold plate 806 and the inlet and outlet openings 807A, 807B of the manifold 807.

It should further be appreciated that, although the inlet and outlet openings 807A, 807B of the manifold 807 are shown as overlapping a central region of the integrated cooling assembly 800, this is non-limiting and in other embodiments inlet and outlet openings of a manifold may be separated more than a width or length of an integrated cooling assembly (i.e. positioned beyond the edges of the integrated cooling assembly) and an opening adaptor may be configured to fluidly connect the manifold to a cold plate of the integrated cooling assembly by compensating the positional difference between the inlet and outlet openings of the cold plate and the inlet and outlet openings of the manifold.

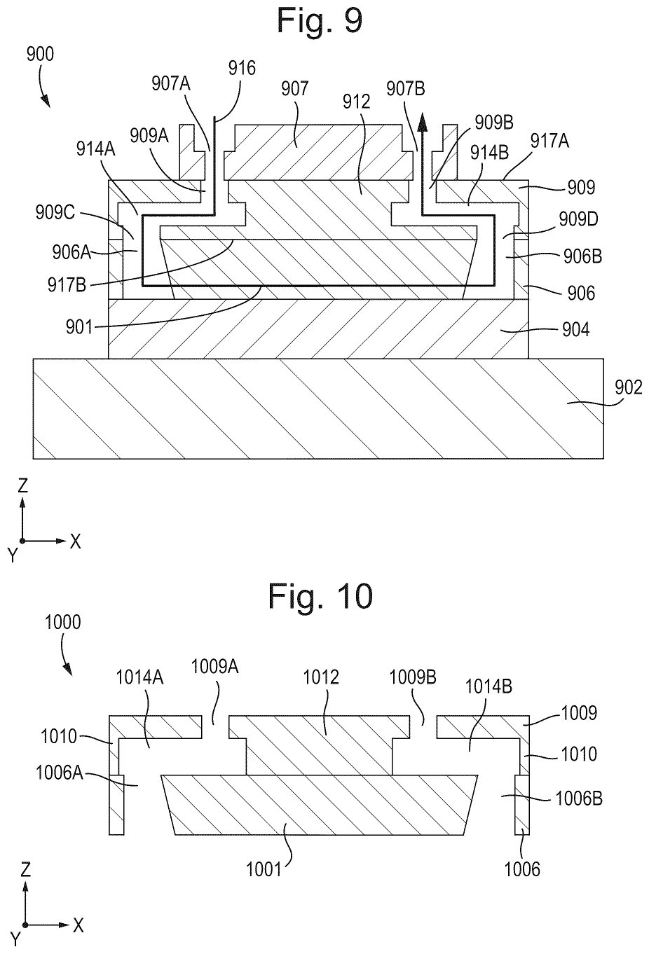

FIG. 9 illustrates an integrated cooling assembly 900 according to one or more embodiments. The integrated cooling assembly 900 may be disposed on a substrate 902. The integrated cooling assembly 900 may comprise a semiconductor device 904, a cold plate 906 attached to the semiconductor device 904, and an opening adaptor 909 attached to the cold plate 906. The opening adaptor 909 may comprise a first side 917A, a second side 917B opposite the first side 917A, an inlet fluid chamber volume 914A, and an outlet fluid chamber volume 914B. The first side 917A of the opening adaptor 909 may comprise a first inlet opening 909A and a first outlet opening 909B spaced apart by a second distance. The second side 917B of the opening adaptor 909 may comprise a second inlet opening 909D and a second outlet opening 909C spaced apart by a first distance different from the second distance. The inlet and outlet fluid chamber volumes 914A, 914B may be separated by a divider 912. The second side 917B of the opening adaptor 909 may comprise extending portions laterally extending away from a lower part of sidewalls of the divider 917 (i.e. a portion closest to the cold plate 906). The extending portions of the second side 917B of the opening adaptor 909 may define a lower wall of the inlet and outlet fluid chamber volumes 914A, 914B. Further, the extending portions of the second side 917B of the opening adaptor 909 collectively with sidewalls of the opening adaptor 909 may define the second inlet opening 909D and the second outlet opening 909C.

The cold plate may comprise a coolant channel 901, a third inlet opening 906A and a third outlet opening 906B spaced apart by the first distance. The second side 917B of the opening adaptor 909 may be attached to a side of the cold plate 906 comprising the third inlet opening 906A and the third outlet opening 906B such that the coolant channel 901 is in fluid communication with the inlet fluid chamber volume and the outlet fluid chamber volume 914A, 914B. The second inlet opening 909D may at least partially overlap and be in fluid communication with the third outlet opening 906B and the second outlet opening 909C may at least partially overlap and be in fluid communication with the third inlet opening 906A.

A manifold 907 may connect to the opening adaptor 909. The manifold 906 may comprise an inlet opening 907A and an outlet opening 907B spaced apart by the second distance. The inlet opening 907A of the manifold 907 may be in fluid communication with the inlet opening 909A of the opening adaptor 909 and the outlet opening 907B of the manifold 907 may be in fluid communication with the outlet opening 909B of the opening adaptor 909.

Arrow 916 illustrate a coolant flow path. The coolant flow path 916 may enter through the inlet opening 907A of the manifold 907, enter the inlet coolant chamber volume 914A through the inlet opening 909A of the opening adaptor 909, exit the inlet coolant chamber volume 914A through the outlet opening 909C of the opening adaptor 909, enter the coolant channel 901 through the inlet opening 906A of the cold plate 906, travel across the semiconductor device 904 to cool the semiconductor device 904 by absorbing heat, exit the coolant channel 901 through the outlet opening 906B of the cold plate, enter the outlet coolant chamber volume 914B through the inlet opening 909D of the opening adaptor 909, exit the outlet chamber volume 914B through the outlet opening 909B of the opening adaptor 909 and exit through outlet opening 907B of the manifold 907.

FIG. 10 illustrates an integrated cooling assembly 1000 according to one or more embodiments, which is not attached to a semiconductor device. Here, the integrated cooling assembly 1000 may comprise an opening adaptor 1009 attached to a cold plate 1006, but the integrated cooling assembly 1000 does not include (e.g., omits) a semiconductor device. The opening adaptor 1009 may comprise an inlet opening 1009A, an outlet opening 1009B, sidewalls 1010, and a divider 1012 between the sidewalls 1010. The cold plate 1006 may comprise a first opening 1006A and a second opening 1006B spaced apart by a first distance and in fluid communication with a coolant channel 1001. The sidewalls 1010 and the divider 1012 of the opening adaptor 1009 both extend downwardly to the cold plate 1006 to define an inlet chamber volume 1014A and an outlet chamber volume 1014B therebetween. The inlet and outlet openings 1009A, 1009B of the opening adaptor 1009 are spaced apart by a second distance different from the first distance. The coolant channel 1001 is in fluid communication with the inlet chamber volume and the outlet chamber volume 1014A, 1014B via the first and second openings 1006A, 1006B of the cold plate 1006.

The integrated cooling assembly 1000 may be disposed on any suitable semiconductor device.

It should be appreciated that in the embodiments of FIGS. 2C to 10 the position of the inlet and outlet openings of a cold plate (for examples the cold plate 206, 506, 806, 906 and 1006) is merely exemplary and non-limiting. In some embodiments, the cold plate may comprise one or more inlets positioned at or near a center of the cold plate and one or more outlets positioned near an edge or periphery of the cold plate (or vice versa). In some embodiments, an inlet or outlet of the cold plate may be aligned (or slightly offset) with a respective inlet or outlet of a manifold, in such embodiments outlet or inlet chamber(s) may only be provided for any other inlet(s) or outlet(s) that are misaligned between the manifold and the cold plate.

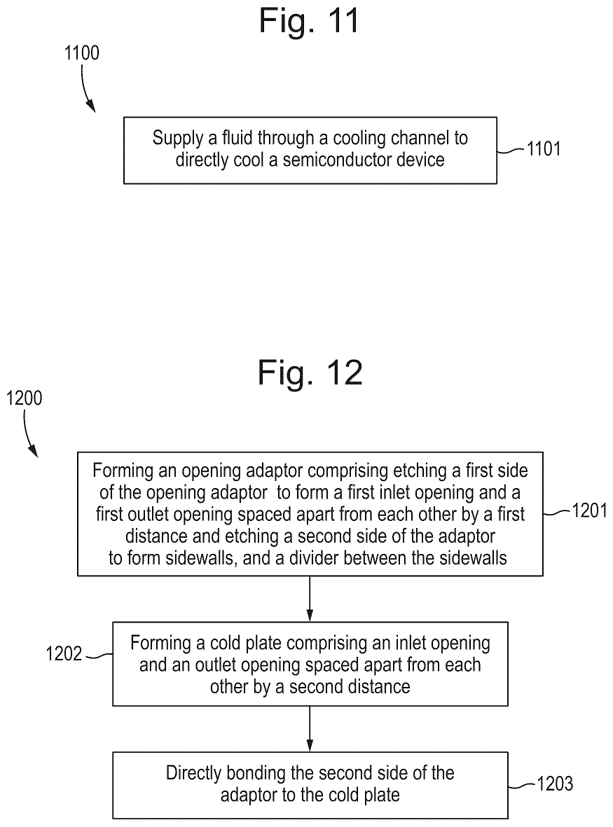

FIG. 11 is a method 1100 of using a device package in accordance with one or more embodiments. At block 1101, a fluid is supplied through a cooling channel to directly cool a semiconductor device. For example, with reference to FIG. 1 and FIG. 2A, a coolant fluid may be supplied (e.g., delivered) into an inlet opening of the package cover 208 and an inlet opening of the sealing material layer 222 from coolant lines 108. The coolant fluid may subsequently pass through cooling channel 210 within a semiconductor device 204. The coolant fluid may subsequently exit through an outlet opening of the package cover 208 and outlet opening of the sealing material layer 222 and into coolant lines 108.

FIG. 12 is a method 1200 of manufacturing an integrated cooling assembly in accordance with one or more embodiments. The method comprise at bock 1201, forming an opening adaptor comprising: etching a first side of the opening adaptor to form a first inlet opening and a first outlet opening spaced apart by a first distance, etching a second side of the opening adaptor to form sidewalls, and a divider between the sidewalls. The etching may similar to or the same as the etching process discussed above in relation to method 60. At block 1202, forming a cold plate comprising an inlet opening and an outlet opening spaced apart by a second distance. The cold plate may be formed as discussed above in relation to method 60. At block 1203, directly bonding the second side of the adaptor to the cold plate. The direct bonding may be a hybrid bonding as discussed above in relation to method 60.

The embodiments discussed above are intended to be illustrative and not limiting. One skilled in the art would appreciate that individual aspects of the cooling assemblies, device packages, and methods discussed herein may be omitted, modified, combined, and/or rearranged without departing from the scope of the disclosure.

1. An integrated cooling assembly comprising:
a semiconductor device;
an opening adaptor comprising an inlet opening, an outlet opening, sidewalls, and a divider between the sidewalls; and
a cold plate attached between the semiconductor device and the opening adaptor, the cold plate comprising a first opening and a second opening spaced apart by a first distance and in fluid communication with a coolant channel, wherein:
at least a portion of a first side of the cold plate is spaced apart from the semiconductor device to define the coolant channel therebetween;
the sidewalls and the divider of the opening adaptor extend downwardly to a second side of the cold plate to define an inlet chamber volume and an outlet chamber volume therebetween;
the inlet and outlet openings of the opening adaptor are spaced apart by a second distance different from the first distance; and
the coolant channel is in fluid communication with the inlet chamber volume and the outlet chamber volume via the first and second openings of the cold plate.

2. The integrated cooling assembly according to claim 1, wherein:
the inlet chamber volume at least partially overlaps and is in fluid communication with the first opening of the cold plate; and
the outlet chamber volume at least partially overlaps and is in fluid communication with the second opening of the cold plate.

3. The integrated cooling assembly according to claim 1, wherein the inlet chamber volume and the outlet chamber volume are separated from the coolant channel by portions of an upper surface of the cold plate.

4. An integrated cooling assembly comprising:
a semiconductor device,
a cold plate attached to the semiconductor device, and
an opening adaptor comprising a first side, a second side opposite the first side, an inlet fluid chamber volume, and an outlet fluid chamber volume, wherein:
the first side of the opening adaptor comprises a first inlet opening and a first outlet opening spaced apart by a second distance;
the second side of the opening adaptor comprises a second inlet opening and a second outlet opening spaced apart by a first distance different from the second distance;
the cold plate comprises a coolant channel, a third inlet opening and a third outlet opening spaced apart by the first distance;
the second side of the opening adaptor is attached to a side of the cold plate comprising the third inlet opening and the third outlet opening; and
the coolant channel is in fluid communication with the inlet fluid chamber volume and the outlet fluid chamber volume.

5. The integrated cooling assembly according to claim 4, wherein the second inlet opening at least partially overlaps and is in fluid communication with the third outlet opening and the second outlet opening at least partially overlaps and is in fluid communication with the third inlet opening.

6. The integrated cooling assembly according to claim 4, wherein the inlet and outlet fluid chamber volumes are separated by a divider.

7. The integrated cooling assembly according to claim 1, wherein the first distance is greater than the second distance.

8. The integrated cooling assembly according to claim 7, wherein the first distance is between 1 to 10 cm.

9. The integrated cooling assembly according to claim 1, wherein the semiconductor device is a first semiconductor device and the integrated cooling assembly further comprises:
a second semiconductor device disposed horizontally adjacent to the first semiconductor, and
a heat sink disposed above the second semiconductor device,
wherein the heat sink extends laterally above a portion of the opening adaptor.

10. The integrated cooling assembly according to claim 9, wherein the integrated cooling assembly further comprises a third semiconductor device disposed horizontally adjacent to the first semiconductor device, wherein:
the first semiconductor device is disposed between the second and third semiconductor devices;
a first portion of the heat sink is disposed above the second semiconductor device and a second portion of the heat sink is disposed above the third semiconductor device; and
the first distance is less than a distance between the first and second portions of the heat sink.

11. The integrated cooling assembly according to claim 9, wherein a gap between the first semiconductor device and the second semiconductor device is between 50 to 300 μm.

12. The integrated cooling assembly according to claim 1, wherein the semiconductor device comprises a plurality of integrated circuit dies.

13. The integrated cooling assembly according to claim 1, wherein the opening adaptor comprises silicon, a metal, or a plastic material.

14-15. (canceled)

16. The integrated cooling assembly according to claim 1, wherein the opening adaptor is attached the cold plate by an adhesive and the adhesive forms a fluid seal between the opening adaptor and the cold plate.

17. The integrated cooling assembly according to claim 1, wherein the cold plate comprises silicon and the opening adaptor is attached to the cold plate by direct dielectric bonds.

18. The integrated cooling assembly according to claim 1, wherein the cold plate comprises silicon and the opening adaptor is attached to the cold plate by direct hybrid bonds.

19. The integrated cooling assembly according to claim 1, wherein the cold plate and the semiconductor device are attached by direct dielectric bonds.

20. The integrated cooling assembly according to claim 1, wherein the cold plate and the semiconductor device are attached by direct hybrid bonds.

21. (canceled)

22. The integrated cooling assembly according to claim 1, wherein a backside of the semiconductor device is exposed to the coolant channel.

23-27. (canceled)

28. The integrated cooling assembly according to claim 1, wherein the cold plate comprises a cavity divider to define a plurality of coolant channels.
